(19) United States
(12) Patent Application Publication
(10) Pub. No.: US 2021/0376785 A1
(43) Pub. Date: Dec. 2, 2021

(54) MAGNETICALLY LINKABLE MODULAR SOLAR PANEL SYSTEM

(71) Applicant: Richard Glenn Rhett, JR., Vicksburg, MS (US)

(72) Inventor: Richard Glenn Rhett, JR., Vicksburg, MS (US)

(21) Appl. No.: 17/302,251

(22) Filed: Apr. 28, 2021

Related U.S. Application Data
(60) Provisional application No. 62/983,615, filed on Feb. 29, 2020.

(51) Int. Cl. H02S 30/10; H02S 30/20

(52) U.S. Cl. CPC H02S 30/10; H02S 30/20

(57) ABSTRACT

A modular solar charging system includes a base unit and at least one secondary unit. The base unit has a solar panel, within a base frame, electrically connected to a controller on a first lateral surface of the base frame and has conductive magnetic connectors on a second lateral surface of the base frame electrically connected to the controller. The secondary unit has a solar panel, within a secondary frame, electrically connected to conductive magnetic connectors on a first lateral surface of the secondary frame magnetically linkable to the conductive magnetic connectors on the base unit. The modular solar charging system includes solar panels with affixed electrically conductive magnetic connectors. Each of the solar panels is electrically connected to at least two electrically conductive magnetic connectors. Adjacent electrically conductive magnetic connectors are couplable to form a conductive connection.

### CROSS-REFERENCE TO RELATED APPLICATION

This application claims the benefit of priority of U.S. provisional application number 62/983,615, filed Feb. 29, 2020, the contents of which are herein incorporated by reference.

### BACKGROUND OF THE INVENTION

The present invention relates to solar recharging systems and, more particularly, to solar recharging systems with linkable solar panel modules.

Currently portable solar panel recharging products provide a fixed re-charge power according to the packaged number of solar panels. For example, a user can only increase the watt output of a 7-watt solar panel for use on a camping trip by disassembling and manually linking another solar panel with complicating wiring or buying an entire separate system packaged as a 21-watt or 28-watt panel that is constructed as a fixed, non-adaptable product. Therefore, one does not have the flexibility to increase solar recharging power in an easy and economical fashion. Another challenge camping individuals face is being able to place their solar panel on the roof of their tent to take advantage of sunlight hitting the roof of the tent.

Conventional devices adapt poorly to the ever-changing user environment. They do not offer a modular capability, i.e., an easy way to link multiple solar panels together, to increase and decrease power and weight as required by the user.

As can be seen, there is a need for a solar panel recharge system with easily linkable solar panel modules.

### SUMMARY OF THE INVENTION

The present invention provides a solar panel system comprising a base solar panel module and at least one secondary solar panel module.

In one aspect of the present invention, a modular solar charging system is provided, comprising: a base unit having a solar panel within a base frame, said solar panel electrically connected to a controller on a first lateral surface of the base frame and conductive magnetic connectors on a second lateral surface of the base frame electrically connected to the controller on the first lateral surface of the base frame; and at least one secondary unit, having a solar panel within a secondary frame, said solar panel electrically connected to conductive magnetic connectors on a first lateral surface of the secondary frame magnetically linkable to the conductive magnetic connectors on the base unit.

In another aspect of the present invention, a modular solar charging system is provided, comprising a plurality of solar panels having electrically conductive magnetic connectors affixed thereto, wherein each of the plurality of solar panels is electrically connected to at least two electrically conductive magnetic connectors and wherein adjacent electrically conductive magnetic connectors of the plurality of solar panels are couplable to form a conductive connection.

These and other features, aspects and advantages of the present invention will become better understood with reference to the following drawings, description, and claims.

### BRIEF DESCRIPTION OF THE DRAWINGS

FIG. 1 is a top perspective view of a magnetically linkable solar panel system according to an embodiment of the present invention;

FIG. 2 is a bottom perspective view thereof;

FIG. 3 is an exploded view thereof;

FIG. 4 is a sectional view thereof, taken along line 4-4 in FIG. 1; and

FIG. 5 is a schematic view thereof, showing electrical connections.

### DETAILED DESCRIPTION OF THE INVENTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

Broadly, one embodiment of the present invention is a modular solar charging system comprising at least one base unit magnetically linkable to at least one secondary unit, each unit having a solar panel and electrically conductive magnetic connectors, with wiring connecting the solar panel to the magnetic connectors.

As used herein, a base solar panel module is also referred to as a solar base module or unit and a secondary solar panel module is also referred to as a solar link module or unit.

A solar base may comprise a base frame containing a base unit solar panel, a controller unit, electrically conductive magnetic connectors, and attachment magnets. The controller withstands increased charging capacity. The solar panel may be wired to the controller unit which in turn may be wired to the magnetic connectors.

A solar link may comprise a secondary unit solar panel in a secondary frame with electrically conductive magnetic connectors affixed to opposing sides (i.e., lateral surfaces) of the frame. The solar panel may be wired to the magnetic connectors on one side, which may in turn be wired to the connectors on the opposite side.

The couplable electrically conductive magnetic connectors enable a user to magnetically connect the base module to a secondary solar panel module. Energy is transferred through the electrical connection formed when the panels are linked together with the electrical conducting magnets. The linkable magnetic connection enables a user to quickly add or subtract power and thus change weight, giving the user a modular option for recharging devices when weight is an important consideration. The quick electrical magnetic connection incorporated into the inventive solar panels allows users the ease and versatility needed to handle different conditions as they are camping or traveling.

The system comprises a solar base and as many solar links as correspond to a predetermined amount of power and weight. According to the needs of the user's planned trip or excursion, the user may configure the amount of power and weight they will carry by adding solar links to the solar base. The user may select the number of secondary units corresponding to a predetermined total weight, a predetermined total wattage, and/or a predetermined total voltage. To carry x-lbs and recharge with y-watts, the user may carry 1 Solar Base+z-1 Solar Links, wherein each panel weighs x/z-lbs and provides y/z-watts. To carry a system providing 2y-watts, the user may carry 1 Solar Base+2z-1 Solar Links at y/z-watts each. The invention allows users to have multiple options for charging via solar power, enabling the user to select either a single solar panel designed for a predetermined-wattage or multiple solar panels to achieve the predetermined-wattage. For example, the present invention enables the user to obtain three 7-watt panels and connect them into a 7-watt, 14-watt, or 21-watt configuration, thereby saving resources and adding flexibility. Depending on the wiring of the solar panels, construction of the controller unit, and the size of the solar panels, one may easily change the voltage output, the wattage output, and the weight of the finished products.

In some embodiments, the inventive solar panel system further comprises a component selected from the group consisting of: a female connection at the controller unit, a charge indicator light emitting diode (LED), an overcharge protector, a Universal Serial Bus (USB) port such as USB Type-C®, and combinations thereof. The base unit may further have a power port and a charging cable couplable thereto.

In some embodiments, the solar panel units may have auxiliary magnets. The auxiliary magnets enable the user to control positioning of the unit, solving a placement problem for campers.

In some embodiments, the electrically conductive magnetic connectors may be directly affixed to the solar panels, allowing solar panels to link together quickly and easily for a wide range of uses. In some cases, the controller may be affixed remotely. Adjacent electrically conductive magnetic connectors of adjacent solar panels may be coupled to form conductive connections.

To use the system, the user may simply place the Solar Base on a flat surface and connect a first Solar Link to the Solar Base by holding the magnetic connectors on the first Solar Link close to the correct magnetic connectors on the solar base until the magnets link together. A second Solar Link may be attached to the first Solar Link in the same manner and subsequent Solar Links may be similarly attached. The inventive system is not limited to use during travel as it provides a scalable building block approach which may be used to connect multiple solar panels together on a residential roof or in a multitude of other locations.

A Solar Base unit may be manufactured by placing a solar panel with wiring in a constructed frame, fixing the controller unit to the frame, inserting electrically conducting attachment magnets into the frame, placing auxiliary magnets on the base to enable custom positioning, and connecting the wiring.

A Solar Link unit may be manufactured by placing a solar panel with wiring in a constructed frame, inserting attachment magnets into the frame, fixing magnetic electrical connectors to the frame, and connecting wiring to the connectors on each side so that the solar panel is electrically connected to conductive magnetic connectors.

The materials of manufacture are not particularly limited. Solar panel frames according to the invention may be manufactured from materials selected from the group consisting of: constructed textile, polymer, steel, aluminum, and combinations thereof. The materials may be selected to minimize weight and/or cost.

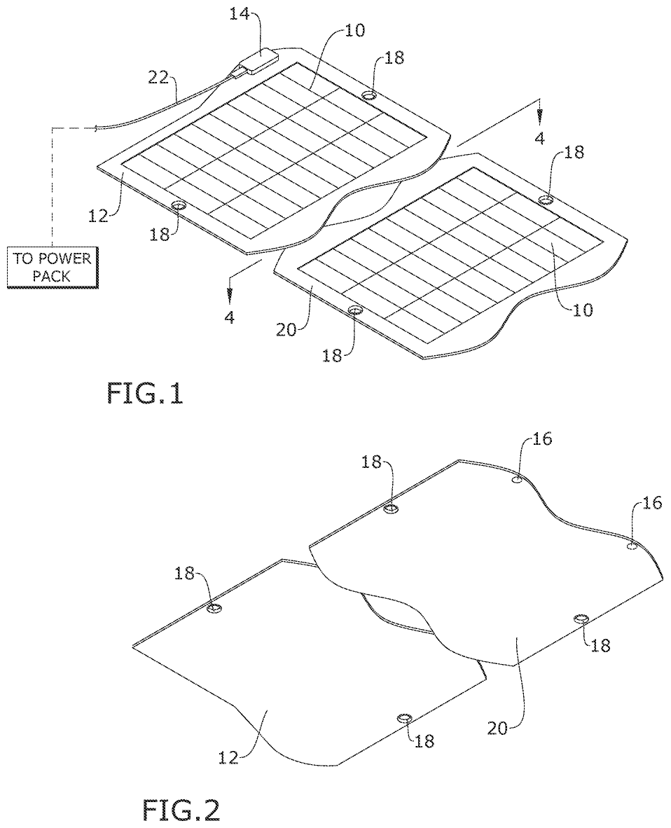

Referring to FIGS. 1 through 5, FIGS. 1, 2, and 4 show a solar base module or controller unit 12 linked or coupled to a solar link module 20 by way of electrical conducting magnets 16. The solar base module 12 and the solar link module 20 each include a solar panel 10 of fixed power capacity held on a supporting frame with grommets 18.

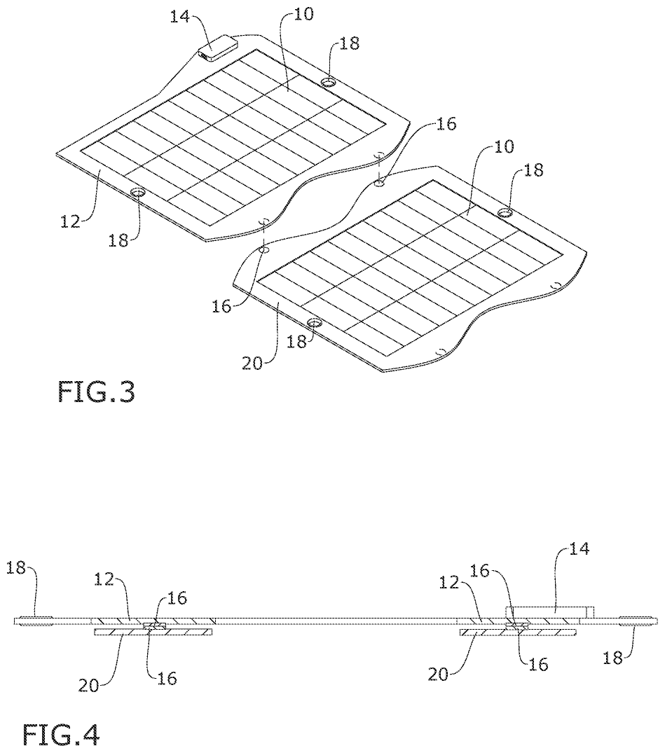

As shown in FIG. 3, the base module 12 has electrical conducting magnets 16 on a first side of the module 12 and a power port 14 and cable 22 on an opposite second side of the module 12. The solar link module 20 has electrical conducting magnets 16 on opposite sides of the solar link module 20 frame.

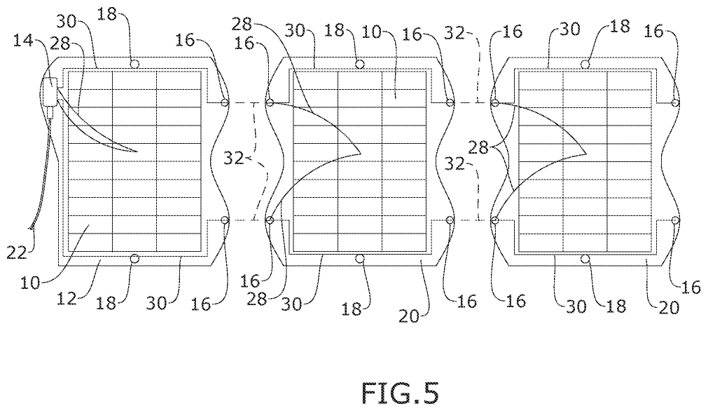

FIG. 5 shows a schematic view illustrating how the solar link modules 20 electrically communicate with the solar base module 12. Each solar panel 10 is connected to electrical conducting magnets 16 on its respective frame with solar panel wiring 28. The electrical conducting magnets 16 on a first side of a solar link module 20 electrically communicate with electrical conducting magnets 16 on a second side of the module 20 by way of connection wiring 30. When the electrical conducting magnets of a pair of modules 12, 20 are coupled, they form a conductive connection 32. The solar link module 20 furthest from the solar base module 12 communicates harvested power to the adjacent solar link module 20 by way of the conductive connection 32, which transfers the power to the next module 12, 20, ultimately delivering the power to the solar base module 12. The user may plug a power pack or battery of a device into the power port 14 with the cable 22 to charge using electrical power converted from the sun's energy.

It should be understood, of course, that the foregoing relates to exemplary embodiments of the invention and that modifications may be made without departing from the spirit and scope of the invention as set forth in the following claims.

What is claimed is:

1. A modular solar charging system comprising:
a base unit having a solar panel within a base frame, said solar panel electrically connected to a controller on a first lateral surface of the base frame and conductive magnetic connectors on a second lateral surface of the base frame electrically connected to the controller on the first lateral surface of the base frame; and
at least one secondary unit, having a solar panel within a secondary frame, said solar panel electrically connected to conductive magnetic connectors on a first lateral surface of the secondary frame magnetically linkable to the conductive magnetic connectors on the base unit.

2. The modular solar charging system of claim 1, wherein a conductive connection is formed when the conductive magnetic connectors of the base frame are coupled to the conductive magnetic connectors of the secondary frame.

3. The modular solar charging system of claim 1, further comprising a component selected from the group consisting of: a female connection at the controller, a charge indicator light emitting diode, an overcharge protector, a universal serial bus port, and combinations thereof.

4. The modular solar charging system of claim 1, wherein the base unit further comprises a power port electrically connected to the controller and a charging cable couplable to the power port.

5. The modular solar charging system of claim 1, wherein the at least one secondary unit further comprises conductive magnetic connectors on a second lateral surface of the secondary frame, said conductive magnetic connectors on the second lateral surface being electrically connected to the conductive magnetic connectors on the first lateral surface.

6. The modular solar charging system of claim 5, comprising more than one secondary unit, the conductive magnetic connectors on the second lateral surface of a first secondary frame being magnetically linkable to the conductive magnetic connectors on the first lateral surface of a second secondary frame.

7. The modular solar charging system of claim 6, comprising a number of secondary units corresponding to a predetermined total weight, a predetermined total wattage, and/or a predetermined total voltage.

8. A modular solar charging system comprising a plurality of solar panels having electrically conductive magnetic connectors affixed thereto, wherein each of the plurality of solar panels is electrically connected to at least two electrically conductive magnetic connectors and wherein adjacent electrically conductive magnetic connectors of the plurality of solar panels are couplable to form a conductive connection.

9. The modular solar charging system of claim 8, further comprising a controller.

10. The modular solar charging system of claim 9, wherein the controller is remotely attached.
